(19) United States
(12) Patent Application Publication
(10) Pub. No.: US 2023/0172392 A1
(43) Pub. Date: Jun. 8, 2023

(54) DOMESTIC PEF COOKING DEVICE AND METHOD FOR OPERATING SAME

(71) Applicant: BSH Hausgeräte GmbH, Munich (DE)

(72) Inventors: Uwe Has, Unterneukirchen (DE); Barbara Heikel, Traunstein (DE); Arnulf Himmel, Traunreut (DE); Bernhard Koch, Inzell (DE); Manfred Steinbacher, Inzell (DE); Edith Wrehde, Nußdorf (DE)

(21) Appl. No.: 17/911,660

(22) PCT Filed: Mar. 3, 2021
(86) PCT No.: PCT/EP2021/055257

§ 371 Date: Sep. 15, 2022

(30) Foreign Application Priority Data
Mar. 19, 2020 (DE) 10 2020 203 522.9

(51) Int. Cl. A47J 36/32; H05B 6/50; H05B 6/62; G01R 27/14; A23L 5/10; A47J 27/00

(52) U.S. Cl. CPC A47J 36/32; H05B 6/50; H05B 6/62; G01R 27/14; A23L 5/15; A47J 27/004

(57) ABSTRACT

A household PEF cooking appliance includes a cooking product container fillable with liquid and cooking product and including, on its inner faces, a plurality of mutually insulated electrodes. An excitation device supplies at least two of the plurality of electrodes with pulsed electric signals, and a resistance measuring device applies a measuring signal to at least two of the plurality of the electrodes in order to measure an associated current signal and to determine a resistance value of a content of the cooking product container. A control device operates the excitation device and the resistance measuring device separately and operates the excitation device based on the resistance value.

The invention relates to a household PEF cooking appliance having a cooking product container which can be filled with liquid and cooking product and which has, on its inner faces, at least two mutually insulated electrodes, an excitation device for supplying at least two of the electrodes with a pulsed electric field and a resistance measuring device designed to determine a resistance value of the contents of the cooking product container. The invention further relates to a method for operating a household PEF cooking appliance, wherein, during operation, the resistance measuring device determines the resistance value of the contents of the cooking product container.

DE 10 2011 080 860 A1 discloses a device for treating raw materials with at least two spaced-apart electrodes which are brought into contact with a controlled electrical energy source, wherein the electrodes are formed in each case by at least two electrically isolated electrode segments, each thereof being connected to the electrical energy source in an electrically controlled manner and each electrode segment being connected to a measuring device which is configured to determine the electrical conductivity between the electrode segments, wherein the electrical energy source is controlled by a control unit and the electrical energy source is controlled and configured to supply electrical energy at least in each case to the two electrode segments, the lowest electrical conductivity therebetween being determined.

However, it is a drawback here that due to the high PEF pulse voltages, the high pulse currents and the relatively short pulse durations (which for example have unpredictable settling times) in PEF cooking appliances, a sufficiently reliable and at the same time cost-effective estimation of the impedance from the evaluation of the PEF voltage signals on the cooking product container is not possible, or only associated with significant effort in terms of circuit technology.

It is the object of the present invention to remedy at least partially the drawbacks of the prior art, and in particular to provide a possibility for PEF cooking in the household with improved operational reliability.

This object is achieved according to the features of the independent claims. Advantageous embodiments form the subject matter of the dependent claims, the description and the drawings.

The object is achieved by a household PEF cooking appliance, having

a cooking product container which can be filled with liquid and cooking product and which has, on its inner faces, at least two mutually insulated electrodes,

an excitation device for supplying at least two of the electrodes with a pulsed electric signal (“PEF signal”) and

a resistance measuring device designed to apply a measuring signal to at least two of the electrodes in order to measure an associated current signal and to determine a resistance value of the contents of the cooking product container, and

a control device which is configured to operate the excitation device and the resistance measuring device, and which is also configured to operate the excitation device on the basis of at least one measured resistance value,

wherein

the control device is configured to operate the excitation device and the resistance measuring device separately.

This results in the advantage that the resistance value of the contents of the cooking product container is able to be determined in a particularly accurate manner, with relatively low and thus cost-effective effort in terms of circuit technology, and thus it is possible react in a particularly reliable manner to the contents of the cooking product container with safety-critical resistance values. In cooking appliances in the industrial or professional field, however, costs for a circuit/electronics play only a relatively minor role.

A PEF (“pulsed electric field”) cooking appliance is understood to mean, in particular, a cooking appliance which receives the cooking product between electrodes and, by applying PEF signals to the electrodes, generates a pulsed electrical field therebetween, the cooking product located between the electrodes being cooked thereby. To this end, the contents of the cooking product container has to be electrically conductive. This is typically achieved by the contents consisting of liquid and cooking product. In this case solid cooking product, for example a piece of meat, is able to be placed in liquid (for example water) or the cooking product itself is already liquid, for example soup. PEF cooking appliances are known in principle, so that the principle of PEF cooking is not explained in more detail hereinafter.

The fact that the cooking product container (which may also be denoted as the treatment chamber) has at least two mutually insulated electrodes, encompasses in particular that the cooking product container has in its wall at least two mutually insulated (in the empty state), in particular flat, electrodes which are arranged, in particular, at opposing positions of the cooking product container. These two electrodes may be regarded as an electrode pair. In principle, the cooking product container can have one or more electrode pairs, to which PEF signals are able to be applied together or independently of one another.

The excitation device serves to supply the PEF signals to the electrodes of at least one electrode pair. In this case, in principle all suitable excitation devices are able to be used. The voltage of the PEF signals may be up to 600 V or even more, for example 600 V to 750 V.

The resistance measuring device is configured to apply a measuring signal, which is different from the PEF signals, to a least two of the electrodes or to at least one electrode pair in order to determine or measure the resistance value of the contents of the cooking product container. In principle, the type and shape of the measuring signal is not limited and may comprise a DC voltage signal and/or an AC voltage signal of any frequency and any shape. The resistance value may be an ohmic resistance or an impedance—depending on the measuring signal.

For determining an impedance, the resistance measuring device may be configured, in particular, to apply a measuring voltage signal to an electrode pair of the cooking product container, and to measure the associated current. The impedance may be determined therefrom in a manner known in principle.

The excitation device and the resistance measuring device are operated or controlled by means of a control device. In particular, the control device is configured to operate the excitation device as a function of at least one measured resistance value. The control device may thus use the measured resistance value as an input variable for controlling the excitation device.

The control device is also configured to operate the excitation device and the resistance measuring device separately. The separate operation encompasses, in particular, that PEF signals and measuring signals are not supplied at the same time to the same electrode pair, which significantly improves the measuring accuracy.

One development is that the cooking product container is fixedly installed in the PEF cooking appliance. One development is that the cooking product container is able to be removed by the user.

One embodiment is that the excitation device and the resistance measuring device are connected to the same electrodes and the control device is configured to operate the excitation device and the resistance measuring device at different times (“alternately”). This corresponds to an option which is able to be implemented in a particularly simple manner in terms of construction, i.e. not supplying PEF signals and measuring signals to the same electrode pair at the same time.

One development is that the excitation device has at least one voltage source and at least one pair of switches, wherein the switches of the voltage source and the electrodes of the cooking product container are interposed. For example, at least one switch is able to be arranged between a first connection of the voltage source and a first electrode of the cooking product container and at least one further switch is able to be arranged between a second connection of the voltage source and a second electrode of the cooking product container. The switches are able to be controlled by means of the control device, in particular selectively switchable so as to be openable or in a blocking state and switchable so as to be closable or in a conductive state. Thus the advantage may be achieved that by suitable switching of the switches, the PEF pulses are able to be generated from the output voltage of the voltage source. One development is that a pulsed AC voltage is able to be applied to the electrodes, wherein the PEF pulses successively applied to an electrode have a commutating polarity.

Thus the voltage source may be, for example, a DC voltage source which provides the advantage of a shaping of the PEF pulses which may be implemented in a particularly simple manner as well as a use of a simple and inexpensive voltage source, even for high voltage values. By means of the switches a pulsed AC voltage may be generated from the DC voltage. Alternatively, for example, a power correction filter which is connected downstream of an AC supply voltage may be used as the voltage source.

Generally, one or more pairs of switches may be present. The resistance measuring device is thus able to be connected via a separate pair of switches, which also are able to be controlled by the control device, to at least two electrodes of the cooking product container.

The excitation device may also be denoted as a pulse generator. The contents of the cooking product container represents for the excitation device an electrical load which has a capacitive and an ohmic component.

One embodiment with two pairs of switches is that the voltage source of the excitation device

is able to be connected by a first voltage connection via a first switch of a first pair of switches of the excitation device to the first electrode,

is able to be connected by the first voltage connection via a second switch of a second pair of switches of the excitation device to the second electrode,

is able to be connected by a second voltage connection via a second switch of the first pair of switches to the second electrode, and

is able to be connected by the second voltage connection via a first switch of the second pair of switches to the first electrode

and the resistance measuring device

is able to be connected via a first switch of a third pair of switches to one of the two electrodes and

is able to be connected via a second switch of a third pair of switches to the other of the two electrodes

wherein

the control device is configured to switch the switches such that, when the switches of the third pair are closed, the switches of the first and second pair are opened, and vice versa.

Thus the advantage is achieved that an accurate determination of the resistance is possible with a small degree of effort in terms of circuit technology. In cooking appliances in the industrial or professional field, however, costs for a circuit/electronics play only a relatively minor role.

Since when the switches of the third pair are closed, the switches of the first and second pair are open, PEF signals are prevented from being applied to the electrodes or the at least one electrode pair during a measurement of the resistance value, and conversely the resistance measuring device is electrically isolated from the electrodes when PEF signals are applied to the electrodes. In the “reverse” case, for example, the switches of the first and second pair may be selectively opened or closed in order to apply the PEF signals to the electrodes.

The third switches may also be regarded as components of the resistance measuring device.

One embodiment is that the excitation device is connected to at least one electrode pair for applying the PEF signals (hereinafter denoted as the “operating electrode pair” without limiting the generality) and the resistance measuring device is connected to at least one electrode pair (hereinafter denoted as the “measuring electrode pair” without limiting the generality) of the cooking product container which is electrically isolated from the at least one operating electrode pair (when the cooking product container is empty). The operating electrodes used for generating the PEF field for cooking or heating the cooking product and the measuring electrodes used for measuring the resistance value thus represent different electrodes of the cooking product container. Thus it is advantageously achieved that PEF signals and measuring signals are not able to be supplied at the same time to the same electrode pairs. A further advantage is that the switches of the third switch pair are able to be designed particularly inexpensively since in the open state thereof the typically high PEF pulse voltage applied to the cooking product container is able to be electrically isolated from the measuring device in a particularly reliable manner.

One embodiment, provided in the presence of the at least one operating electrode pair and the at least one measuring electrode pair, is that the control device is configured to operate the excitation device and the resistance measuring device at the same time. Thus the advantage is achieved that the output of the PEF signals is able to be carried out independently of a measuring process. This facilitates carrying out the PEF cooking process, for example by a simplified programming of the control device.

One embodiment, provided in the presence of the at least one operating electrode pair and the at least one measuring electrode pair, is that the control device is configured to operate the excitation device and the resistance measuring device at different times. As a result, a particularly accurate measurement of the resistance value is made possible.

However, a combination of an output of the PEF signals and the resistance measurement simultaneously and at different times is also possible, for example by the operation of the excitation device and the resistance measuring device in a manner which is partially overlapping or staggered over time. In principle, the excitation device and the resistance measuring device may be operated independently of one another with separate operating electrodes and measuring electrodes.

One embodiment with two pairs of switches is that the voltage source of the excitation device

is able to be connected by a first voltage connection via a first switch of a first pair of switches of the excitation device to a first electrode of the operating electrode pair,

is able to be connected by the first voltage connection via a second switch of a second pair of switches of the excitation device to the second electrode of the operating electrode pair,

is able to be connected by a second voltage connection via a second switch of the first pair of switches to the second electrode of the operating electrode pair and

is able to be connected by the second voltage connection via a first switch of the second pair of switches to the first electrode of the operating electrode pair

and the resistance measuring device

is able to be connected via a first switch of a third pair of switches to one of the two electrodes of the measuring electrode pair and

is able to be connected via a second switch of a third pair of switches to the other of the two electrodes of the measuring electrode pair.

This represents a particularly simple implementation of a circuit in terms of circuit technology with separate operating electrodes and measuring electrodes.

One embodiment is that the measuring electrode pair is arranged on at least the same wall or wall region of the cooking product container as the operating electrode pair. As a result, advantageously a compact option is provided for connecting the electrodes.

One development is that an operating electrode occupies a wall over a large surface area, in particular the entire surface area, and namely except for a recess for at least one operating electrode.

One embodiment is that the measuring electrode pair is arranged on at least one wall of the cooking product container which differs from the walls or wall regions on which the operating electrode pair is arranged. As a result, the advantage is achieved that the operating electrodes may occupy the respective walls without a recess for the operating electrode(s).

One development with a rectangular cooking product container is that the operating electrodes and the measuring electrodes are arranged on side walls of the cooking product container.

One embodiment is that the measuring electrode pair protrudes into the cooking product container so as to be spaced apart from one another on the bottom side, whilst the operating electrodes are located on a side wall or wall region. Thus the advantage is achieved that the side walls are able to be occupied with the operating electrodes in a manner which is free in terms of design.

For example, in the case where the cooking product container has a rectangular basic shape, in each case the operating electrodes may be arranged, for example, on two opposing side walls, and

in each case the measuring electrodes may be arranged on the two other opposing side walls,

in each case the two measuring electrodes may be arranged on one of the other opposing side walls;

the measuring electrodes may protrude into the cooking product container on the bottom side;

in each case the two measuring electrodes may be arranged on a wall occupied by an operating electrode;

the two measuring electrodes may be arranged spaced apart from one another on the same wall occupied by an operating electrode.

However, the cooking product container may also have a different, for example cylindrical, basic shape. Moreover, the electrodes (operating and/or measuring electrodes) may be arranged on a bottom and on a cover part of the cooking product container which opposes this bottom and which is able to be lowered into the contents of the cooking product container.

One embodiment is that one of the electrodes is connected to a series resistor and at least the excitation device is configured to supply electric signals to the electrodes via the series resistor. The series resistor provides the advantage that current peaks may be suppressed. In the case where the same electrodes are used for applying the PEF signals and the measuring signals, the resistance measuring device is also able to be connected via the series resistor to the electrode connected thereto, so that both the PEF signals and the measuring signals may be applied to the associated electrode via the series resistor. In the case where the measuring signals are applied to separate measuring electrodes, these measuring signals may be applied directly to the measuring electrodes, i.e. without using the series resistor.

The object is also achieved by a method for operating the PEF cooking appliance, and vice versa. The method is able to be designed in an analogous manner to the PEF cooking appliance and has the same advantages.

The method serves, in particular, for operating a household PEF cooking appliance as described above, wherein during operation of the household PEF cooking appliance the resistance measuring device determines the resistance value of the contents of the cooking product container, and at least one safety-relevant action is triggered when the resistance value falls below a predetermined threshold value. Thus the advantage is achieved that an operational reliability is increased by the evaluation or assessment of the resistance value.

The safety-relevant action may comprise, for example, limiting an electrical power of the PEF signals, a delay to a start of a PEF cooking phase or the output of the PEF signals, a terminating of the PEF cooking phase and/or an output of a message to a user.

By means of this method, it is advantageously possible to consider the case where a user has inadvertently placed a metal part in the cooking product container, for example a clip or needle which holds together a roulade. Without the method, during the PEF cooking phase high electrical currents could be generated in the metal part, whereby the associated cooking product is spoilt (for example burnt in the region of the metal part) and/or the household PEF cooking appliance could be damaged due to the very small load, for example by a short circuit. However, if it is established by means of the resistance measurement that the resistance value has fallen below a predetermined threshold value, such a situation is able to be avoided. The threshold value thus represents a safety threshold value—which is, for example, empirically determined.

Relative to the operation of the household PEF cooking appliance, in principle the resistance measuring device may be operated before, during and/or after a PEF cooking phase or a resistance measurement may be carried out before, during and/or after a PEF cooking phase.

One embodiment is that at least one first safety-relevant action is triggered when the resistance value falls below a predetermined first threshold value, and at least one second safety-relevant action is triggered when the resistance value falls below a predetermined second threshold value which is lower than the first threshold value. Thus advantageously it is possible to react flexibly to different levels of risk. For example, the first threshold value may correspond to a threshold value in which an energy of the PEF signals is limited, but the PEF cooking phase is carried out. The second threshold value may correspond to a threshold value in which the PEF cooking phase has either not been started or has been prematurely terminated.

The message output to the user may comprise, for example, an output of an optical and/or acoustic signal and/or an output of a text message, etc.

One embodiment is that during an operation of the excitation device, in particular during a PEF cooking phase, it is monitored whether an electrode voltage applied to the operating electrode pair has dropped by a predetermined amount due to the voltage pulses output by the excitation device and, if this is the case, the resistance value is measured by means of the resistance measuring device. The dropping of the electrode voltage thus serves as a trigger to carry out a resistance measurement. Thus the advantage is achieved that the resistance measurement is carried out in a particularly appropriate manner.

The above-described properties, features and advantages of this invention and the manner in which they are achieved will become clearer and more clearly understood in connection with the following schematic description of an exemplary embodiment which is described in more detail in connection with the drawings.

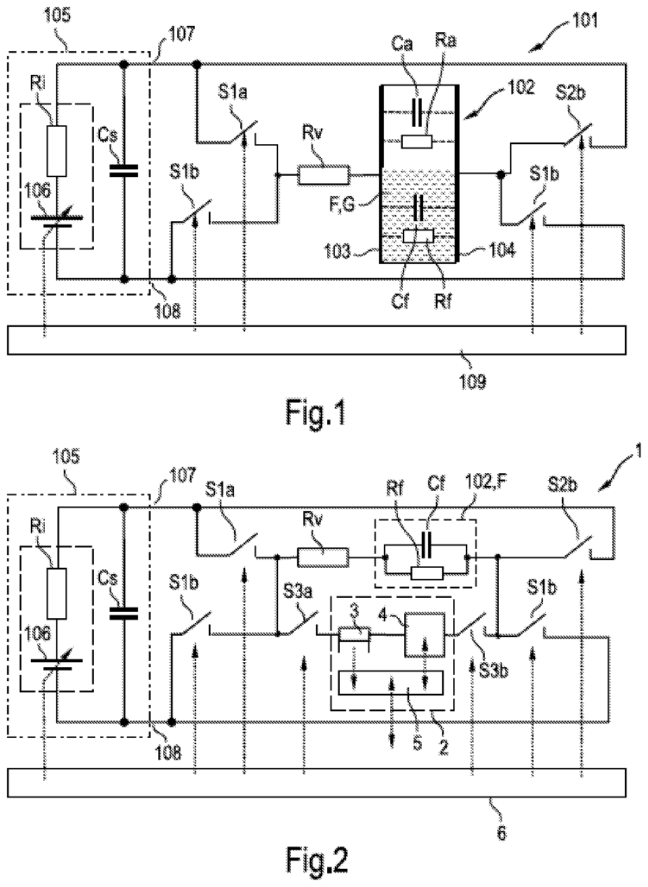

FIG. 1 shows a circuit diagram of a PEF cooking appliance;

FIG. 2 shows a circuit diagram of a PEF cooking appliance according to a first exemplary embodiment according to the invention;

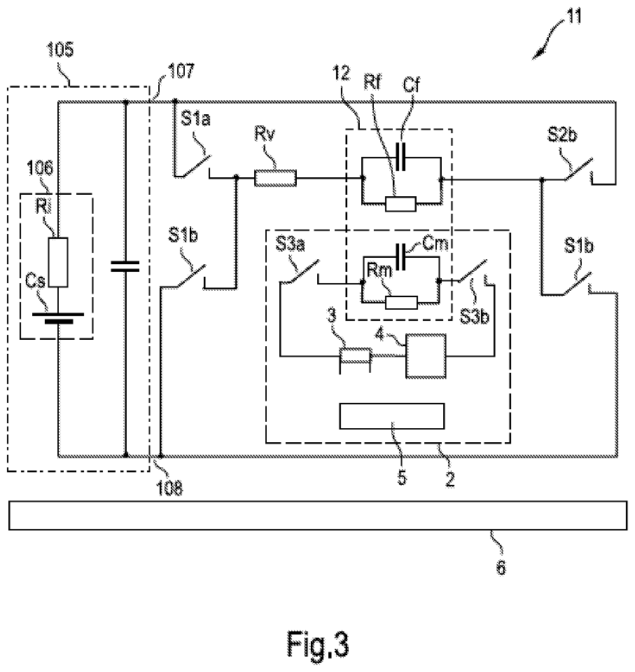

FIG. 3 shows a circuit diagram of a PEF cooking appliance according to a second exemplary embodiment according to the invention;

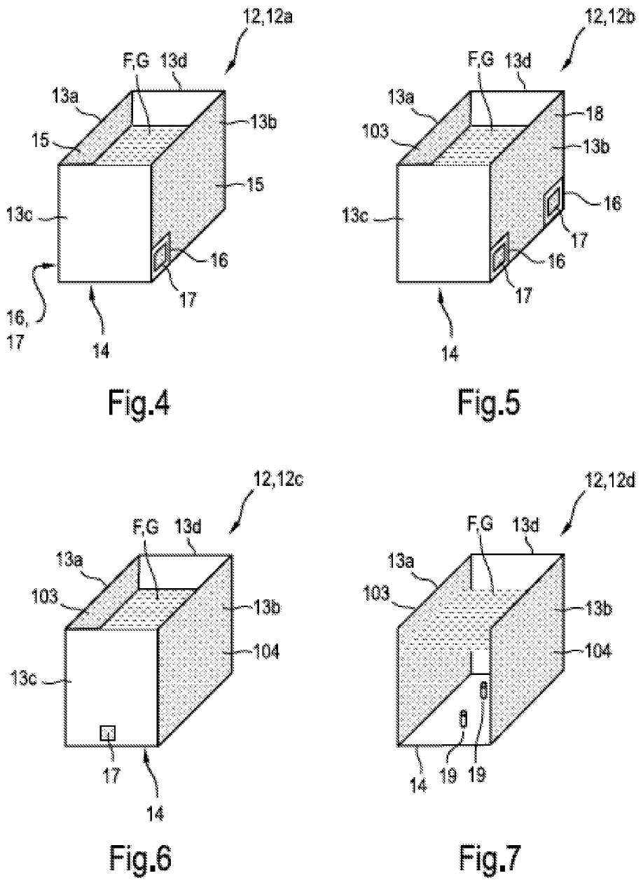

FIG. 4 shows a first cooking product container according to the invention;

FIG. 5 shows a second cooking product container according to the invention;

FIG. 6 shows a third cooking product container according to the invention; and

FIG. 7 shows a fourth cooking product container according to the invention.

FIG. 1 shows a circuit diagram of a PEF cooking appliance 101. The PEF cooking appliance 101 has a cooking product container 102 which is able to be filled with liquid F and cooking product G (not illustrated separately) and which has a first electrode 103 and a second electrode 104 on opposing sides. The electrodes 103, 104 are exposed on the inner face of the cooking product container 102 and as a result come into contact with the contents F, G of the cooking product container 102.

The PEF cooking appliance 101 also has a voltage generator 105 as an energy source for supplying a pulsed electrical PEF signal to the two electrodes 103, 104. The voltage generator 105 here by way of example has, for example, a controllable DC voltage source 106 with an (optionally intrinsic) internal resistance Ri and a back-up capacitor Cs electrically connected in parallel thereto, which ensures the highest possible pulse currents.

The voltage generator 105 is able to be connected by a first voltage connection 107 via a first switch S1a of a first pair of switches S1a, S1b to the first electrode 103 via a series resistor Rv for suppressing current peaks, and via a second switch S2b of a second pair of switches S2a, S2b to the second electrode 104. The voltage generator 105 is also able to be connected by a second voltage connection 108 via a second switch S1b of the first pair of switches S1a, S1b to the second electrode 104, and via a first switch S2a of the second pair of switches S2a, S2b via the series resistor Rv to the first electrode 103. The four switches S1a, S1b, S2a, S2b serve for the pulse shaping of the PEF signals and to this end are alternately opened and closed in pairs, i.e. here by way of example either the switches S1a and S1b or the switches S2a and S2b are closed. Due to the short pulse duration the switches S1a, S1b, S2a, S2b are preferably electronic switches, for example IGBTs, but are not limited thereto. The switches S1a, S1b, S2a, S2b and the voltage source 106 are controlled by means of a control device 109 as indicated by the dotted arrows.

The excitation device 105, S1a, S1b, S2a, S2b comprises here both the voltage generator 105 and the switches S1a, S1b, S2a, S2b.

Generally the cooking product container 102 is not completely filled. The capacitance of the capacitor formed by the electrodes 103, 104 and the contents of the cooking product container 102 is thus composed of the capacitance Cf of the part filled with the liquid (for example water) and the capacitance Ca of the part filled only with air, which corresponds to a parallel circuit of the two capacitances Ca and Cf. The ohmic resistance between the two electrodes 103, 104 is similarly composed of the ohmic resistance Rf of the part filled with water and the ohmic resistance Ra of the part only filled with air, which corresponds to a parallel circuit of the two resistances Ra, Rf.

A measurement of the voltage applied to the series resistor Rv permits the calculation of the electrical current flowing through the cooking product container 102. Together with the electrode voltage which is applied to the cooking product container 102 or the electrodes 103, 104 thereof and which is able to be determined from the voltage level of the PEF pulses and the resistance value of the series resistor Rv, the impedance of the contents F, G of the cooking product container 102 is able to be concluded in a manner known in principle.

In this case, an estimation or measurement of the impedance which is as accurate as possible is expedient, since the operational reliability is able to be increased thereby. There are substantially two reasons for determining the operational reliability: (1) when metal is located in the cooking product container 102, a short circuit could be triggered thereby. (2) If the impedance is accurately known, this is able to be taken into consideration during the shaping of the PEF pulses, for example relative to the voltage level and/or pulse duration thereof. Due to the high pulse voltages, high pulse currents and relatively short pulse durations (which in practice cause unpredictable settling times) in household PEF cooking appliances 101, however, a reliable and at the same time cost-effective determination of the impedance from the evaluation of the voltage signals on the series resistor Rv and on the cooking product container 102 is practically impossible or only possible with significant effort in terms of circuit technology.

FIG. 2 shows a circuit diagram of a PEF cooking appliance 1 which is designed for improved determination of the impedance of the contents F, G. The PEF cooking appliance 1 represents a modification of the PEF cooking appliance 101. In this case, and as in FIG. 3 described below, the capacitor 102 is shown with the contents F, G as a simplified equivalent circuit with a capacitance Cf and an ohmic resistance Rf, since typically Ca<<Cf and Ra>>Rf.

In addition to the PEF cooking appliance 101 the PEF cooking appliance 1 has a resistance measuring device 2 which is designed to apply a measuring signal to the two electrodes 103, 104 for determining the impedance of the contents F, G. In the present case, the resistance measuring device 2 is able to be connected via a first switch S3a of a third pair of switches S3a, S3b via the series resistor Rv to the first electrode 103, and via a second switch S3b of the third pair of switches S3a, S3b to the second electrode 104. The resistance measuring device 2 has here by way of example a shunt 3, a signal generator 4 for generating the measuring signals and an evaluation device 5 for determining the impedance.

The control device 6 may communicate with the evaluation device 5 and is additionally configured for the operation of the resistance measuring device 2 and the switches S3a and S3b (which may also be regarded as components of the resistance measuring device 2). The control device 6 is also configured to operate the excitation device 105, S1a, S1b, S2a, S2b on the basis of the determined impedance. In particular, the control device 6 operates the switches S3a, S3b of the third pair S3a, S3b such that when they are closed or switched to a conductive state, the switches of the first and second pair S1a, S1b, S2a, S2b are opened. If conversely PEF pulses are applied to the electrodes 103, 104, the switches S3a, S3b are opened or switched to a blocking state.

If the switches S3a, S3b are closed, the signal generator 4 may generate a measuring signal for the impedance measurement, the voltage thereof being known very accurately, for example relative to the frequency, shape and/or voltage value thereof. Since the resistance value of the series resistor Rv is also very accurately known, the electrode voltage applied to the electrodes 103 and 014 is able to be derived with a high degree of accuracy. By measuring the voltage on the shunt resistor or shunt 3, additionally the electrical current, which flows in the circuit formed during the impedance measurement, is able to be accurately determined, for example by means of the evaluation device 5. With the knowledge of the electrode voltage and the current, by means of the evaluation device 5 the impedance value of the contents F, G of the cooking product container 102 is able to be determined and the capacitance Cf thereof and the ohmic resistance Rf estimated in a manner known in principle.

The household PEF cooking appliance 1 is able to be operated such that, during an operation, the resistance measuring device 2 determines the impedance of the cooking product container 2 or the contents F, G thereof and the control device 6 triggers at least one safety-relevant action when the impedance value falls below a predetermined threshold value. This is able to be configured such that when the impedance value falls below a predetermined first threshold value, at least one first safety-relevant action (for example a limit of the voltage level of the PEF pulses, optionally with the output of a message to a user) is triggered and when the impedance value falls below a predetermined second threshold value which is lower than the first threshold value, at least one second safety-relevant action is triggered, for example the excitation device 105, S1a, S1b, S2a, S2b is not operated and a corresponding message is output to a user.

The control device 6 may also be configured, for example programmed, such that during an operation of the excitation device 105, S1a, S1b, S2a, S2b or a PEF cooking phase it is monitored whether an electrode voltage applied to the operating electrode pair 103, 104 has dropped within a predetermined time period by a predetermined amount due to the PEF voltage pulse output by the excitation device 105, S1a, S1b, S2a, S2b and, if this is the case, the impedance value is measured by means of the resistance measuring device 2. This is able to be implemented such that a discharge speed of the electrode voltage is monitored and, when this discharge speed is greater than a predetermined threshold value, the impedance measurement is carried out. In this case, the effect is taken into consideration that this drop is due to the discharge of the capacitance of the cooking product container 102 through the internal ohmic resistance of the cooking product container. If, for example, metal is located in the cooking product container 102, the capacitor provided by the cooking product container 102 may be more rapidly discharged than without metal. This monitoring may additionally or alternatively take place, for example, for carrying out an impedance measurement before the start of a PEF cooking phase and/or after the end thereof.

The only drawback of this PEF cooking appliance 1 is that in practical use the switches S3a and S3b in the open state have to separate the high voltage of the PEF signals reliably from the resistance measuring device 2. This requires relatively expensive switches S3a and S3b. In cooking appliances in the industrial or professional field, costs for a circuit/electronics play only a relatively minor role.

FIG. 3 shows a circuit diagram of a PEF cooking appliance 11 which eliminates the drawback of the PEF cooking appliance 1. The PEF cooking appliance 1 now uses a cooking product container 12 which has separate electrodes for applying the PEF signals (“operating electrodes” 15, 18, 103, 104) and electrodes for applying the measuring signals (“measuring electrodes” 17, 19) as explained in more detail in the following FIG. 4 to FIG. 7. The switches S3a and S3b in this case connect the resistance measuring device 2 directly to the measuring electrodes 17, 19, whilst the operating electrodes 15, 18, 103, 104, similar to the PEF cooking appliance 1, are connected via the switch pairs S1a and S1b or S2a and S2b and via the series resistor Rv to the excitation device 105, S1a, S1b, S2a, S2b. As a result, the use of relatively expensive switches S3a and S3b may be dispensed with. Additionally, the advantage is achieved that a resistance measurement is able to be selectively carried out at the same time or alternately with the imposition of the PEF signals.

When using separate measuring electrodes 17, 19 it may arise that the electrical current flowing through the contents F, G of the cooking product container 12 differs from a current which would be generated when applying the measuring signal to the operating electrodes 15, 18, 103, 104, for example due to a different size and/or position of the measuring electrodes 17, 19, in comparison with the operating electrodes 15, 18, 103, 104. Thus the impedance determined by the resistance measuring device 2 would deviate from the impedance present during a PEF operation, as indicated by the measured capacitance Cm and the measured resistance Rm. However, the impedance determined by the resistance measuring device 2 still correlates with the impedance present during PEF operation. This deviation may be resolved by the impedance determined via the measuring electrodes 17, 19 being converted into the impedance present during the PEF operation. This may be converted, for example, by using characteristic curves—which are, for example, calculated or empirically determined—and which are stored for example in the evaluation device 15 or in the control device 6. To this end, a set of characteristic curves, with a plurality thereof, may also be used, wherein the individual characteristic curves are able to be assigned, for example, to different filling levels, cooking products, etc.

FIG. 4 shows a cooking product container 12 in a first version 12a. The cooking product container 12a has by way of example a rectangular basic shape with four side walls 13a, 13b, 13c, 13d and a bottom 14 and is filled here with liquid F (for example water) and cooking product G (not shown). Here operating electrodes 15 of an operating electrode pair which are electrically isolated from one another when the cooking product container 12a is empty are attached to the left-hand side wall 13a and the right-hand side wall 13b on the inner face over a large surface area. No operating electrodes are attached to the front side wall 13c and the rear side wall 13d but they could be attached in principle.

Each of the two operating electrodes 15 has—here by way of example on a corner—a recess 16 in which a measuring electrode 17 is located on the inner face, spaced apart and electrically isolated from the respective operating electrode 15.

If the cooking product container 12a is inserted into the PEF cooking appliance 11, one of the two operating electrodes 15 corresponds in terms of connection technology and function to the first electrode 103 and the other of the two operating electrodes 15 corresponds in terms of connection technology and function to the second electrode 103. The measuring electrodes 17 are connected to the switches S3a or S3b.

The control device 6 may be designed to be functionally analogous to the control device 6 described in FIG. 2.

FIG. 5 shows a cooking product container 12 in a second version 12b. The cooking product container 12b has a basic shape which is the same as that of the cooking product container 12a, wherein both measuring electrodes 17 are now arranged, however, on the same (here the right-hand) side wall 13b so as to be spaced apart in respective recesses 16 of the operating electrode 18. The measuring electrode pair 17, 17 is thus arranged on the same side wall 13b of the cooking product container 12 as the operating electrode 18. The left-hand operating electrode may correspond to the first operating electrode 103 of the cooking product container 102 (alternatively the second operating electrode 104).

FIG. 6 shows a cooking product container 12 in a third version 12c. The cooking product container 12c has a basic shape which is the same as that of the cooking product container 12a, wherein both measuring electrodes 17 are now attached, however, to the side walls 13c or 13d on the inner face. The measuring electrode pair 17, 17 is thus arranged on those side walls 13c, 13d of the cooking product container 12c which differ from the side walls 13a, 13b on which the operating electrode pair 103, 104 is arranged. As a result, the operating electrodes may correspond to the operating electrodes 103 and 104 of the cooking product container 102. This provides the advantage that no recesses have to be incorporated in the operating electrodes 103, 104.

FIG. 7 shows a cooking product container 12 in a fourth version 12d. The cooking product container 12d also has a basic shape which is the same as that of the cooking product container 12a, wherein both measuring electrodes 19 now protrude, however, into the cooking product container 12d on the bottom side. As a result, the operating electrodes may correspond to the operating electrodes 103 and 104 of the cooking product container 102. This also provides the advantage that no recesses have to be incorporated in the operating electrodes 103, 104. The measuring electrodes 19 are also able to be provided and mounted in a particularly simple manner.

However, in principle, mixed forms of the cooking product container 12 are also possible, for example a variant in which a measuring electrode 17 located on the same side wall 13a or 13b becomes an operating electrode 15, and the other measuring electrode 17 or 19 is located on a wall 13c, 13d or 14 of the cooking product container 12 on which none of the operating electrodes 103 and 104 are arranged, etc.

Naturally, the present invention is not limited to the exemplary embodiment shown.

Thus circuit variants with only two switches or more than four switches are also possible. A plurality of operating electrode pairs may also be present, to which, for example, PEF-signals may be supplied independently of one another.

Generally, “a”, “one”, etc. is able to be understood to mean a singular or a plurality, in particular in the sense of “at least one” or “one or more”, etc. provided this is not explicitly excluded, for example by the expression “exactly one”, etc.

### LIST OF REFERENCE NUMERALS

1 PEF cooking appliance
2 Resistance measuring device
3 Shunt
4 Signal generator
5 Evaluation device
6 Control device
11 PEF cooking appliance
12 Cooking product container
12a-12d Cooking product container
13a-13d Side walls of cooking product container
14 Bottom of cooking product container
15 Operating electrode
16 Recess
17 Measuring electrode
18 Operating electrode
19 Measuring electrode
101 PEF cooking appliance
102 Cooking product container
103 First electrode
104 Second electrode
105 Voltage generator
106 Voltage source
107 First voltage connection of voltage generator
108 Second voltage connection of voltage generator
109 Control device
Ca Capacitance of part of cooking product container filled with air
Cf Capacitance of part of cooking product container filled with liquid
Cm Measuring capacitance
Cs Back-up capacitor
F Liquid
G Cooking product
Ra Ohmic resistance of cooking product container filled with air
Rf Ohmic resistance of cooking product container filled with liquid
Ri Internal resistance
Rm Measuring resistance
Rv Series resistor
S1a First switch of a first pair of switches
S1b Second switch of a first pair of switches
S2a First switch of a second pair of switches
S2b Second switch of a second pair of switches
S3a First switch of a third pair of switches
S3b Second switch of a third pair of switches

1-13. (canceled)

14. A household PEF cooking appliance, comprising:
a cooking product container fillable with liquid and cooking product and including a plurality of mutually insulated electrodes on an inner face of the cooking product container;
an excitation device configured to supply at least two of the plurality of electrodes with pulsed electric signals;
a resistance measuring device configured to apply a measuring signal to at least two of the plurality of the electrodes in order to measure an associated current signal and to determine a resistance value of a content of the cooking product container; and
a control device configured to operate the excitation device and the resistance measuring device separately and to operate the excitation device based on the resistance value.

15. The household PEF cooking appliance of claim 14, wherein the excitation device and the resistance measuring device are connected to a same one of the plurality of the electrodes, said control device configured to operate the excitation device and the resistance measuring device at different times.

16. The household PEF cooking appliance of claim 14, wherein the excitation device includes a voltage source, a first pair of switches, with one of the first pair of switches configured to connect the voltage source to one of the at least two of the plurality of electrodes via a first voltage connection, and a second pair of switches, with one of the second pair of switches configured to connect the voltage source to another one of the at least two of the plurality of electrodes via the first voltage connection, wherein another one of the first pair of switches is configured to connect the voltage source to the other one of the at least two of the plurality of electrodes via a second voltage connection and another one of the second pair of switches is configured to connect the voltage source to the one of the at least two of the plurality of electrodes via the second voltage connection, and further comprising a third pair of switches, with one of the third pair of switches configured to connect the resistance measuring device to one of the at least two of the plurality of electrodes and with another one of the third pair of switches configured to connect the resistance measuring device to another one of the at least two of the plurality of electrodes, said control device configured to switch the first, second and third pairs of switches such that, when the switches of the third pair of switches are closed, the switches of the first and second pairs are opened, and vice versa.

17. The household PEF cooking appliance of claim 14, wherein a pair of the plurality of electrodes is an operating electrode pair connected to the excitation device, and another pair of the plurality of electrodes is an measuring electrode pair which is connected to the resistance measuring device and isolated from the operating electrode pair.

18. The household PEF cooking appliance of claim 17, wherein the control device is configured to operate the excitation device and the resistance measuring device at a same time.

19. The household PEF cooking appliance of claim 17, wherein the control device is configured to operate the excitation device and the resistance measuring device at different times.

20. The household PEF cooking appliance of claim 17, wherein the excitation device includes a voltage source, a first pair switches, with one of the first pair of switches configured to connect the voltage source to one of the operating electrode pair via a first voltage connection, and a second pair of switches, with one of the second pair of switches configured to connect the voltage source to another one of the operating electrode pair via the first voltage connection, wherein another one of the first pair of switches is configured to connect the voltage source to the other one of the operating electrode pair via a second voltage connection and another one of the second pair of switches is configured to connect the voltage source to the one of the operating electrode pair via the second voltage connection, and further comprising a third pair of switches, with one of the third pair of switches configured to connect the resistance measuring device to one of the measuring electrode pair and with another one of the third pair of switches configured to connect the resistance measuring device to another one of the measuring electrode pair.

21. The household PEF cooking appliance of claim 17, wherein the measuring electrode pair is arranged on at least a same wall of the cooking product container as the operating electrode pair.

22. The household PEF cooking appliance of claim 17, wherein the measuring electrode pair is arranged on a wall of the cooking product container which wall differs from walls on which the operating electrode pair is arranged.

23. The household PEF cooking appliance of claim 17, wherein the measuring electrode pair is configured to protrude into the cooking product container on a bottom side.

24. The household PEF cooking appliance of claim 14, further comprising a series resistor connected to one of the at least two of the plurality of electrodes, said excitation device configured to supply electric signals to the plurality of electrodes via the series resistor.

25. A method for operating a household PEF cooking appliance, said method comprising:
applying with a resistance measuring device a measuring signal to at least two electrodes of a cooking product container in order to measure an associated current signal;
during operation, determining with the resistance measuring device a resistance value of a content of the cooking product container; and
triggering a first safety-relevant action when the resistance value falls below a predetermined first threshold value.

26. The method of claim 25, further comprising triggering a second safety-relevant action when the resistance value falls below a predetermined second threshold value which is lower than the predetermined first threshold value.

27. The method of claim 25, further comprising:
supplying with an excitation device the at least two electrodes as an operating electrode pair with pulsed electric signals;
during operation of the excitation device, monitoring whether an electrode voltage applied to the operating electrode pair has dropped by a predetermined amount due to voltage pulses output by the excitation device; and
measuring the resistance value by the resistance measuring device, when the electrode voltage applied to the operating electrode pair has dropped by the predetermined amount.
